(19) United States
(12) Patent Application Publication
(10) Pub. No.: US 2002/0039819 A1
(43) Pub. Date: Apr. 4, 2002

(54) Method for manufacturing a field effect transistor

(76) Inventors: Guiseppe Curello, Catania (IT); Albrecht Kieslich, Radebeul (DE)

Correspondence Address: LERNER AND GREENBERG, P.A., Post Office Box 2480, Hollywood, FL, 33022-2480, US

(21) Appl. No.: 09/883,821

(22) Filed: Jun. 18, 2001

(30) Foreign Application Priority Data
Jun. 16, 2000 (DE) 100 29 659.9

(51) Int. Cl. H01L 21/8238

(52) U.S. Cl. 438/231; 438/305

(57) ABSTRACT

A method for manufacturing field effect transistors with a reduced pn-type junction capacitance between the source and/or the drain, is described. A substrate is provided with an additional implantation step with a high energy level and a small dose. A reduced pn-type junction capacitance accelerates the switching speed of a transistor. The described method can easily be integrated into existing methods for manufacturing field effect transistors.

### BACKGROUND OF THE INVENTION

Field of the Invention

The present invention relates to a method for manufacturing a field effect transistor. The present invention relates in particular to a method for manufacturing MOS field effect transistors for integrated circuits, in particular dynamic random access memories (DRAMs) and embedded DRAM components.

The pursuit of ever faster, highly integrated electronic circuits is coming increasingly to depend on minimizing the delays caused by the transistors. This applies to analog circuits, digital circuits and memory modules that usually have field effect transistors and, in particular, MOS or CMOS field effect transistors.

The switching speed of field effect transistors is determined essentially by the product of the load capacitance of the transistor which has to be charged during the switching and the supply voltage divided by a current which is used for charging. The load capacitance is made up here of a plurality of parasitic capacitances which each make contributions of different sizes to the load capacitance depending on the configuration of the transistor. Important contributions to the load capacitance are generally a capacitance of a gate to a substrate, a capacitance between the gate and a drain, a capacitance of a pn-type junction of the drain and/or source to the substrate and a capacitance that is caused by contacts.

A wide range of measures have been taken according to the prior art in order to keep the delays during the switching of field effect transistors low. First, attempts are made to make available the largest possible current so that the capacitances can be charged more quickly. Furthermore, the source/drain regions are doped as highly as possible in order to minimize the resistance of the drain and source.

Further measures consist in making the parasitic capacitances of a field effect transistor as low as possible. This is generally achieved by increasingly reducing the gate width of a field effect transistor, as a result of which the capacitance of the substrate is reduced. However, the aforesaid measures have already been developed to their full potential so that a further reduction of the switching delays can be achieved in this way only with a high degree of expenditure.

### SUMMARY OF THE INVENTION

It is accordingly an object of the invention to provide a method for manufacturing a field effect transistor which overcomes the above-mentioned disadvantages of the prior art methods of this general type, in which a simple and cost-effective method for manufacturing a field effect transistor with an increased switching speed is described.

With the foregoing and other objects in view there is provided, in accordance with the invention, a method for manufacturing a field effect transistor. The method includes the steps of providing a substrate having a surface layer composed of a material of a first conductivity type; producing a gate oxide layer on the substrate; applying a gate electrode on the gate oxide layer; carrying out a first implantation step for forming source/drain regions with a first dopant of a second conductivity type, with a first energy level and a first dose; and carrying out a second implantation step with a second dopant of the second conductivity type, with a second energy level and a second dose. The second energy level is greater than the first energy level and the second dose is smaller than the first dose, with a result that a capacitance of a pn-type junction from the source/drain regions to the substrate is reduced.

The first implantation step refers to the implantation that essentially determines the conductivity of the source and/or the drain. It is the implantation with the highest dose in the source region and/or the drain region. It does not necessarily have to be the first implantation for manufacturing a field effect transistor or for manufacturing the drain and/or source of the field effect transistor. For this reason, the term first implantation step is not meant to refer to implantations that exert, for example, a correcting function in the source region and/or drain region, such as a lightly doped drain (LDD) implantation which reduces the electrical field peaks at the edge of the drain region.

The dopant of the first implantation step may be composed of all materials which generate the respective opposite conductivity type to that of the substrate. In particular therefore boron if the substrate is an n conductivity type, or phosphorus and/or arsenic if the substrate is a p conductivity type. The energy with which the ionized doping atoms or molecules are accelerated toward the surface layer determines the depth of the doping profile maximum and shape of the doping profile. The implantation is normally followed by a heat treatment so that the dopant atoms diffuse further into the substrate and can be activated in the lattice as electron donors or electron acceptors.

The first energy level and the first dose relate to the acceleration energy and the dose in the first implantation step. Because the first dose is the largest of possibly a plurality of source and/or drain implantations, it generally determines the layer resistance at the surface of the source and/or the drain.

The second implantation step is carried out with dopant materials of the same conductivity type as in the first implantation step, but with a higher energy level and a smaller dose. The objective of the second implantation step is to cause the steep dopant profile edge that drops toward the center of the substrate to drop less steeply by superposing a second dopant profile with a lower dose. In this way, a soft pn-type junction (graded junction) can be generated to the substrate, which, with the same voltage, generates a greater depth of the depletion zone between the drain/source and substrate than an abrupt dopant profile. The greater depletion zone depth reduces the capacitance between the drain/source and the substrate. It is preferred here if the capacitance of the pn-type junction between the source/drain region and the substrate is reduced by at least 3%, preferably at least 5%.

The method according to the invention has the advantage that, owing to the higher energy level and lower doping of the second implantation step, the dopant profile of the first implantation step changes only insignificantly from the surface to the dopant profile maximum so that the layer resistance value of the source and the drain and the static characteristic curve behavior of the field effect transistor are largely retained. For example, the short channel effect behavior is not influenced by the second implantation step. This also ensures easy integration of the method according to the invention into an existing processing line.

The pn-type junction capacitance, can constitute up to 50% of the entire parasitic transistor capacitance in highly integrated logic circuits (see the reference IEEE J. Solid State Circuits SC_{—}19, R. J. Bayuns et al., page 755, 1984). According to this, the method according to the invention permits a significant reduction in the switching delay of a field effect transistor to be easily achieved.

The first and second implantation steps are preferably executed with the same masking of the drain and/or source, with the result that no additional masking step is required for the second implantation step. This permits the method according to the invention also to be applied to an existing manufacturing process with a little additional effort in terms of work. The first and second implantation steps are preferably executed directly in succession, the order being insignificant. The addition of the second implantation step constitutes only a relatively slight change to an existing manufacturing sequence in this case.

In one preferred embodiment, the dopants of the first implantation step and of the second implantation step are the same. This measure permits the first and second implantation steps to be easily combined to form a single process step, in which all that is necessary is to switch over the energy level from the value of the first energy level to the value of the second energy value at the correct point in time during the processing.

The method according to the invention is preferably used for manufacturing MOS field effect transistors, and specifically for manufacturing CMOS field effect transistors, in particular for manufacturing integrated circuits such as embedded DRAMs or DRAMs having the CMOS FETs.

Other features which are considered as characteristic for the invention are set forth in the appended claims.

Although the invention is illustrated and described herein as embodied in a method for manufacturing a field effect transistor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1-8 are diagrammatic, sectional views of a method for manufacturing an n-type channel and a p-type channel MOS field effect transistor according to the invention;

FIGS. 9-13 are graphs of implantation profiles in a drain/source region of the n-type channel MOSFET according to the prior art and according to four different embodiments according to the invention; and

FIG. 14 is a graph showing a comparison of the threshold voltages of n-type channel MOSFETs according to the prior art and according to four different embodiments according to the invention for various transistor channel lengths.

### DESCRIPTION OF THE PREFERRED EMBODIMENTS

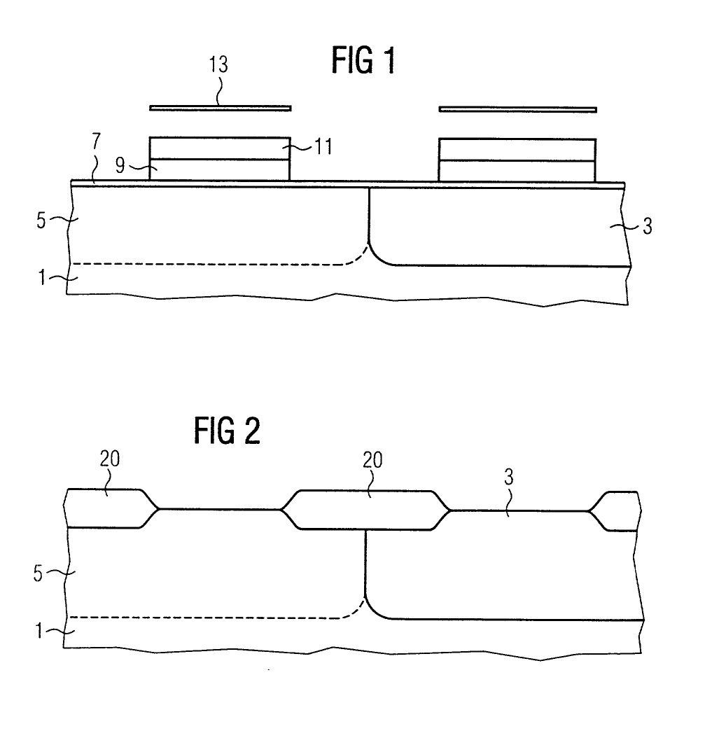

In all the figures of the drawing, sub-features and integral parts that correspond to one another bear the same reference symbol in each case. Referring now to the figures of the drawing in detail and first, particularly, to FIG. 1 thereof, there is shown a substrate 1 made of lightly p-type doped silicon with two adjacent regions 3 and 5. The substrate 1 is prepared according to conventional methods for manufacturing highly integrated CMOS circuits (for example using the 0.4 μm process) and the region 3 having been formed by an n-type implantation with phosphorus, and the region 5 by a p-type implantation with boron. The n-type implanted region 3 is designated below as the n-type well and the p-type implanted region 5 is designated as the p-type well. As a result of a subsequent heat treatment, the dopant atoms of the n-type well and the p-type well diffuse into the substrate 1 so that the n-type and p-type wells extend deeper into the substrate 1 than the subsequent implantations for transistors which are still to be applied.

In addition, a silicon oxide layer 7 is grown onto the substrate surface and in turn has a first polysilicon layer 9 and a first silicon nitride layer 11 applied to it. The layers 9 and 11 having been both patterned by a photolithographic method using a first mask 13. The layers 9 and 11 define a position of two field effect transistors by virtue of the fact that they cover a transistor region during a subsequent oxidation so that a field oxide 20 can be formed only next to the transistors which are to be formed (FIG. 2). Instead of what is referred to as the LOCUS isolation which is shown here, it is also possible to use what is referred to as shallow trench isolation (STI).

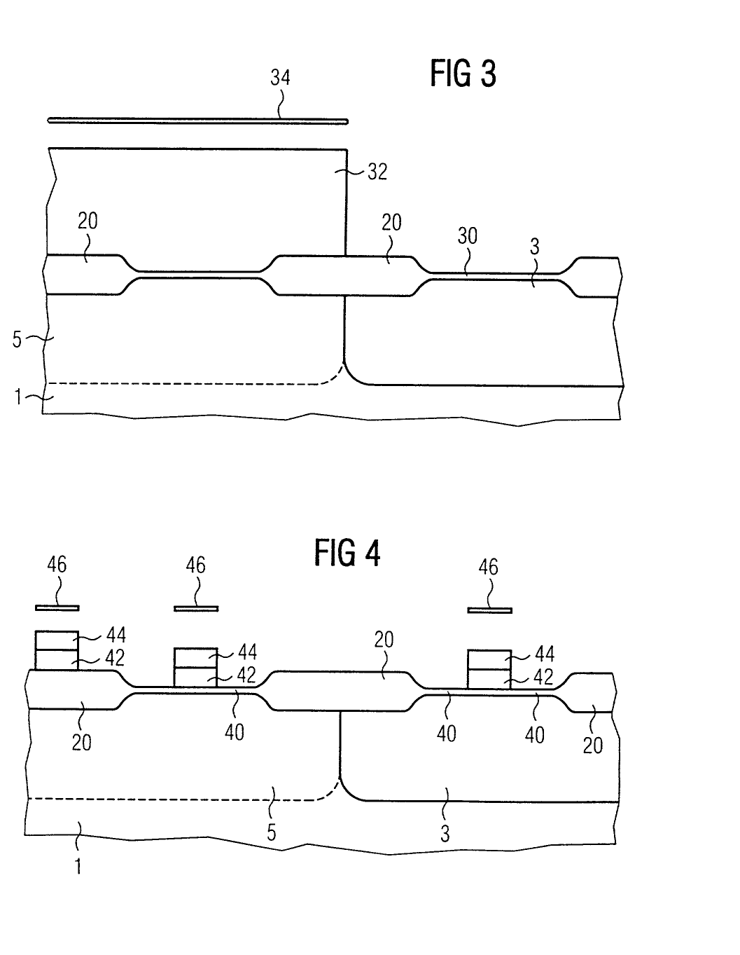

FIG. 3 shows the substrate 1 after a thin screen oxide layer 30 has been grown onto the substrate 1 and an n-type channel with boron atoms for the NMOSFET has been made in the p-type well 5 by an ion implantation (channel doping not visible). The implantation does not go through the field oxide 20, which thus acts as an implantation mask. The open region in the n-type well 3 also receives the n-type implantation. However, the latter is compensated again by one of the following implantations. Afterwards, the p-type well region 5 is covered with a photoresist 32 by a second mask 34. This is followed by an ion implantation with boron for the necessary channel doping for a p-type channel MOS transistor in the n-type well (channel doping not visible).

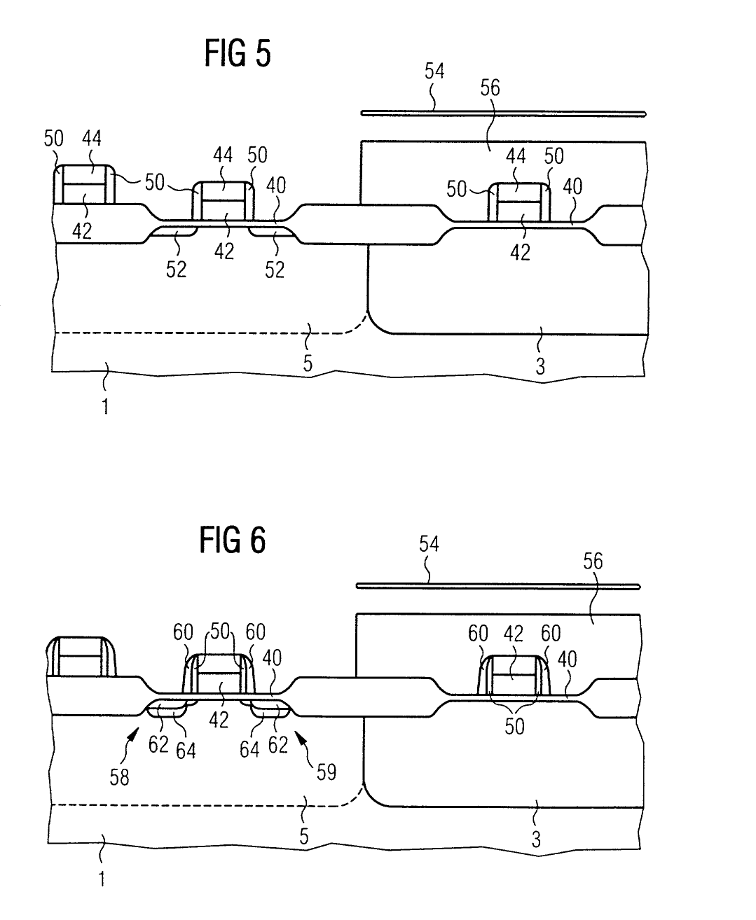

A gate oxide layer for a gate oxide 40 is grown onto the substrate only after the removal of the screen oxide layer 30, and then a doped polysilicon layer for a gate electrode 42 is deposited and an insulating layer 44, for example a TEOS oxide layer, for a gate covering 44 is applied. Subsequently, the TEOS oxide layer 44 and the polysilicon layer 42 are patterned with a third mask 46, with the result that a gate oxide 40 and a gate electrode 42 are generated as the second and third method steps of the method according to the invention (FIG. 4). Subsequently, first silicon oxide spacers 50 are generated at the edges of the gate electrodes 42 and the gate covering 44. The first silicon oxide spacers 50 ensure that there is a minimum distance between a gate edge and source or drain implantation, and thus prevent excessively large electrical fields on the sides of the gate. Subsequently, a screen oxide is applied and the region around the n-type well 3 is selectively covered with a fourth mask 54 by a photoresist 56. An open region defines the n-type channel transistor regions. Lightly doped drain (LDD) regions 52 can then be generated by phosphorus or arsenic implantation in the region of the p-type well 5. The preferred dopant is phosphorus that is introduced into the substrate with a low energy level and a low dose (FIG. 5).

Subsequently, second silicon oxide spacers 60 are generated so that they adjoin the first silicon oxide spacers 50. The region over the n-type well 3 is in turn covered by the fourth mask 54. The two implantation steps which define a source region 59 and a drain region 58 then follow (FIG. 6). The first and second implantation steps are carried out in direct succession, and both are preferably carried out with arsenic. The first implantation step is carried out with a lower energy level than the second implantation step. The second implantation step leads to an implantation 64 that goes deeper into the substrate than an implantation 62 owing to the higher energy level. Both concentration profiles result, when superposed, in an edge which drops away gently toward the interior of the substrate. The edge which drops away toward the surface of the substrate 1 remains unchanged, so that the layer resistance at the surface of the drain and the source is not changed by the second implantation step, and the static transistor behavior, for example threshold voltages and characteristic curves, is retained. Accordingly, a junction capacitance Cⱼ is reduced without the static behavior of the transistors having been changed.

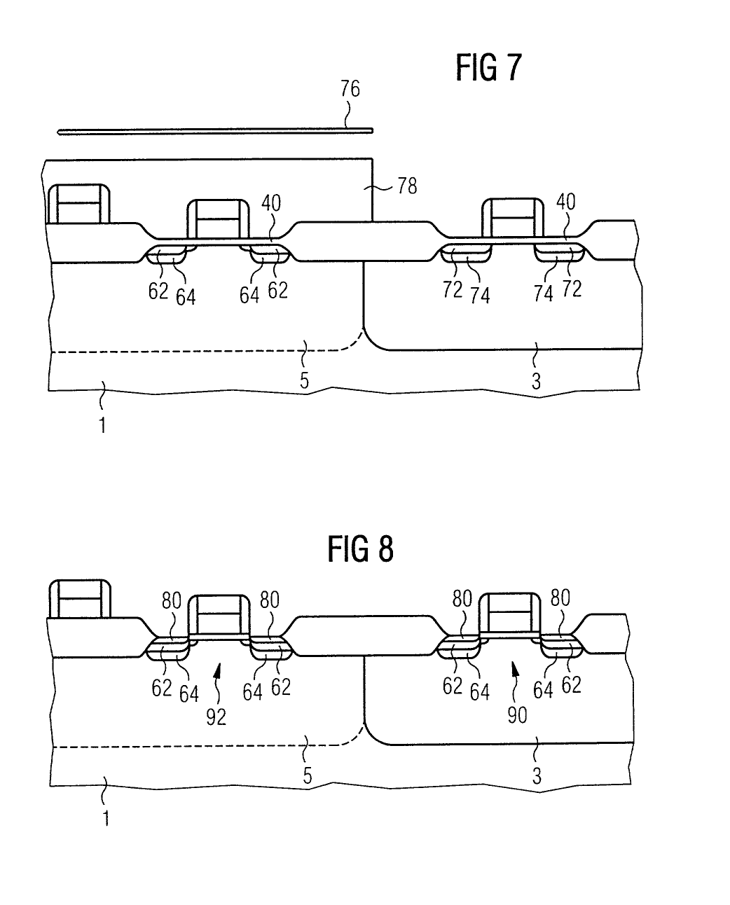

The corresponding implantations for generating the p-type channel MOSFET are then carried out. A photoresist 78 is used to protect the p-type well region 5. A first implantation step with BF₂ then follows leading to a first p-type implantation 72. This is then followed by a second implantation step with BF₂ with a higher energy level and a lower dose, leading to a second p-type implantation 74. Owing to the higher energy level of the second implantation step, the second implantation 74 extends deeper into the substrate 1 (FIG. 7).

As in the case of the n-type channel MOSFET, the order of the first and second implantation step can also be interchanged here. It is to be noted that the p-type channel MOSFET is, in contrast to the n-type channel MOSFET, not provided with the LDD implantation. After the implantation, the photoresist 78 is etched away and a heat treatment is carried out in order to activate the implanted boron atoms.

In order to connect the field effect transistors manufactured in this way, titanium, for example, is then deposited and heat treated so that a self-aligning silicide (salicide) 80 can form over the drain/source regions. The remaining part of the titanium layer is eliminated by a titanium etching step. Finally, this is followed by a further tempering step for optimally forming a barrier layer over the source/drain region. In this way, contacts are made on the source/drain regions of a p-type channel field effect transistor 90 and n-type field effect transistor 92. However, other contacting methods may also be used. The rest of the sequence for manufacturing an integrated circuit with the field effect transistors according to the invention is carried out with methods according to the prior art.

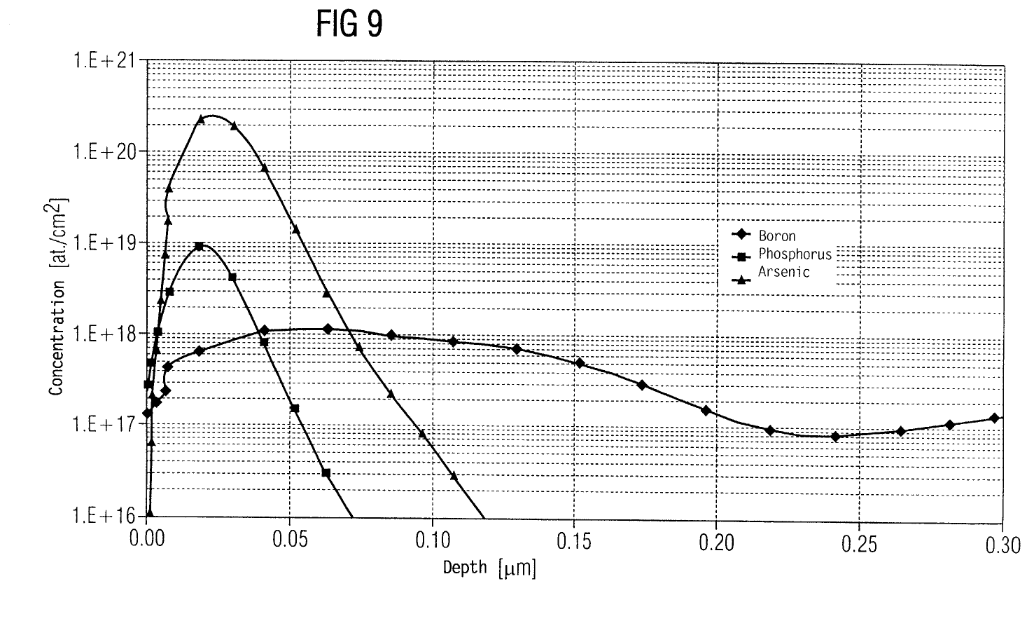

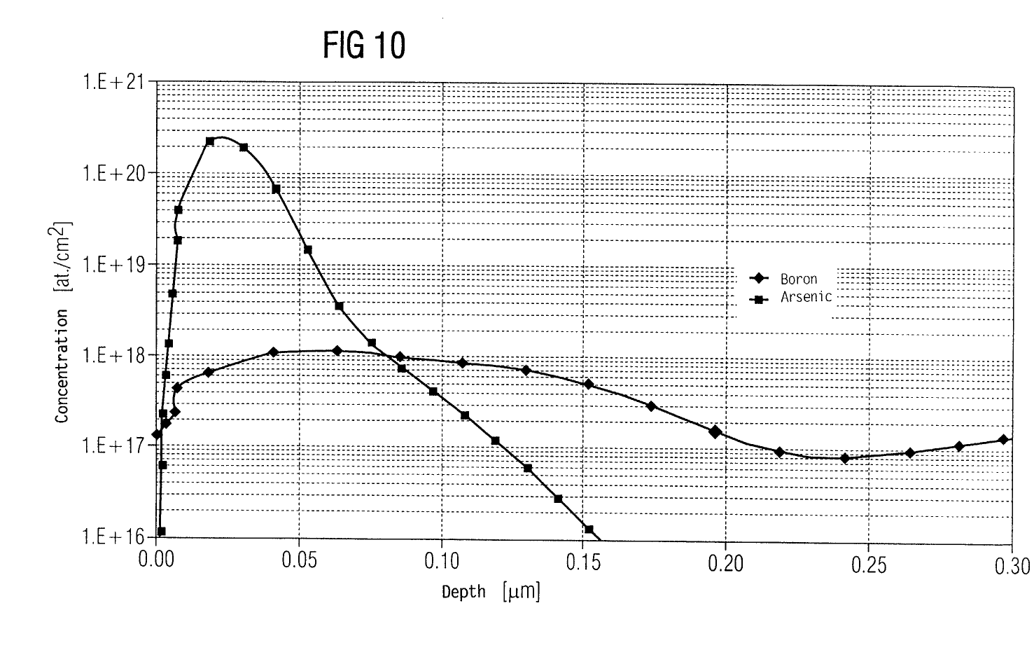

FIGS. 9 to 13 show the simulated doping profiles in the source/drain region for 0.2 technology. Here, FIG. 9 shows an embodiment without a second implantation step, which is thus in accordance with the prior art. FIGS. 10 to 13 show four embodiments according to the invention with different second implantation steps.

FIG. 9 shows three doping profiles in the source/drain region of an n-type channel field effect transistor according to the prior art. The deepest doping profile is a relatively flat boron doping with a concentration of approximately 1*10¹⁷ cm⁻³ to 1*10¹⁸ cm⁻³ here. The implantation represents the p-type well of the transistor and extends to a depth of approximately 200 nm.

Two flat implantations have been introduced into the p-type well. A weak doping with phosphorus with an energy level of 15 keV and a dose of 2*10¹³ cm⁻², which defines the LDD region. Its maximum depth is approximately 30 nm with a doping profile maximum value of approximately 1*10¹⁹ cm⁻³. This implantation serves essentially to reduce the field strength peaks in the edge region of the drain region. A strong doping with arsenic with an energy level of 30 keV and a dose of 6*10¹⁴ cm⁻², which defines the drain and/or the source. Its maximum depth is approximately 35 nm with a maximum doping profile of approximately 3*10²⁰ cm⁻². These two implantations are offset laterally with respect to one another by forming a spacer on the side walls of the gate electrode. The phosphorus implantation is not significant for the following explanations. For this reason, the implantation is no longer shown in FIGS. 10 to 13.

The pn-type junction between the drain/source and the well is at a depth of 70 nm with a doping concentration of approximately 1*10₁₈ cm⁻³. The relatively high net doping concentration in the vicinity of the pn-type junction ensures that the depletion zone is small, which gives rise to a large capacitance Cⱼ and thus greater delay times. The capacitance Cⱼ is, in this case, 1.143 fF/μm², and the overlapping capacitance Cₒᵥₗ is 0.198 fF/μm (see table 1).

FIG. 10 shows two doping profiles in the source/drain region of an n-type channel field effect transistor according to a first embodiment of the invention. The boron doping for the p-type well and the first implantation step correspond to the description of FIG. 9. The second implantation step has been carried out with a second energy level of 90 keV, which is greater than the first level and a second dose of 5*10¹² cm⁻², which is smaller than the first dose. The higher second energy level causes the superposed arsenic doping profile to drop away more gently toward the side of the substrate. This causes the pn-type junction to be softer because the doping edges drop away more gently and the pn-type junction is at a greater depth, i.e. approximately 80 nm. In particular, the doping edge that drops away more gently contributes to the depletion zone depth in the pn-type junction region being greater than in FIG. 9. This in turn reduces the pn-type junction capacitance of 1.143 fF/μm² to 1.105 fF/μm², while the overlapping capacitance Cₒᵥₗ changes only insignificantly at 0.200 fF/μm (see table 1).

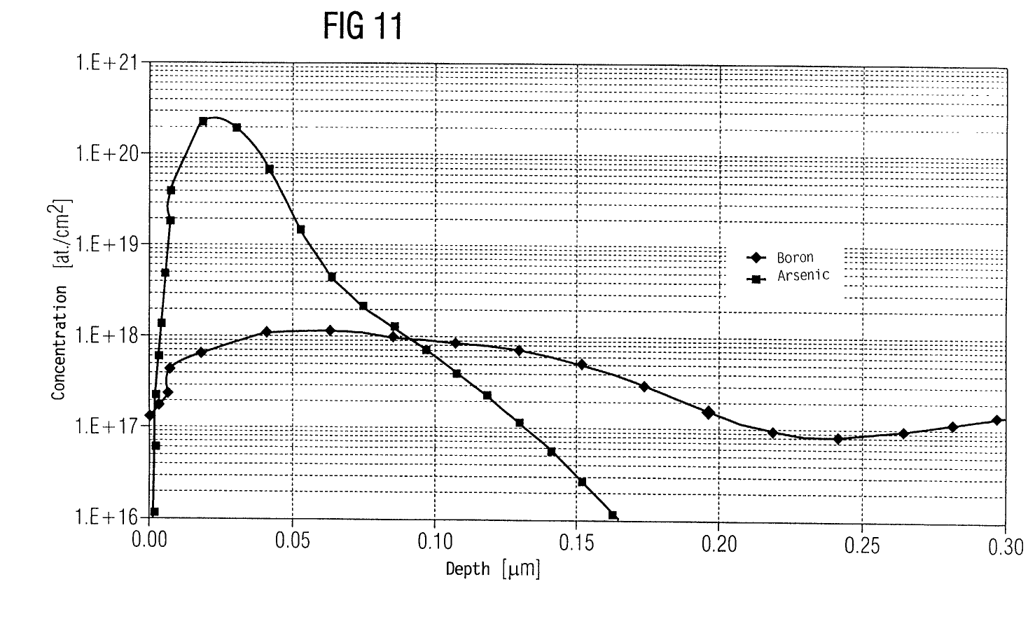

FIG. 11 shows the implantation profiles according to a further embodiment of the invention in which the second implantation has been carried out with a larger dose, i.e. 1*10¹³ cm⁻². This causes the pn-type junction to be at a depth of 95 nm, and the doping edge to drop away more gently toward the substrate once more. The pn-type junction capacitance is therefore only 1.081 fF/μm², while the overlapping capacitance Cₒᵥₗ changes only insignificantly at 0.201 fF/μm.

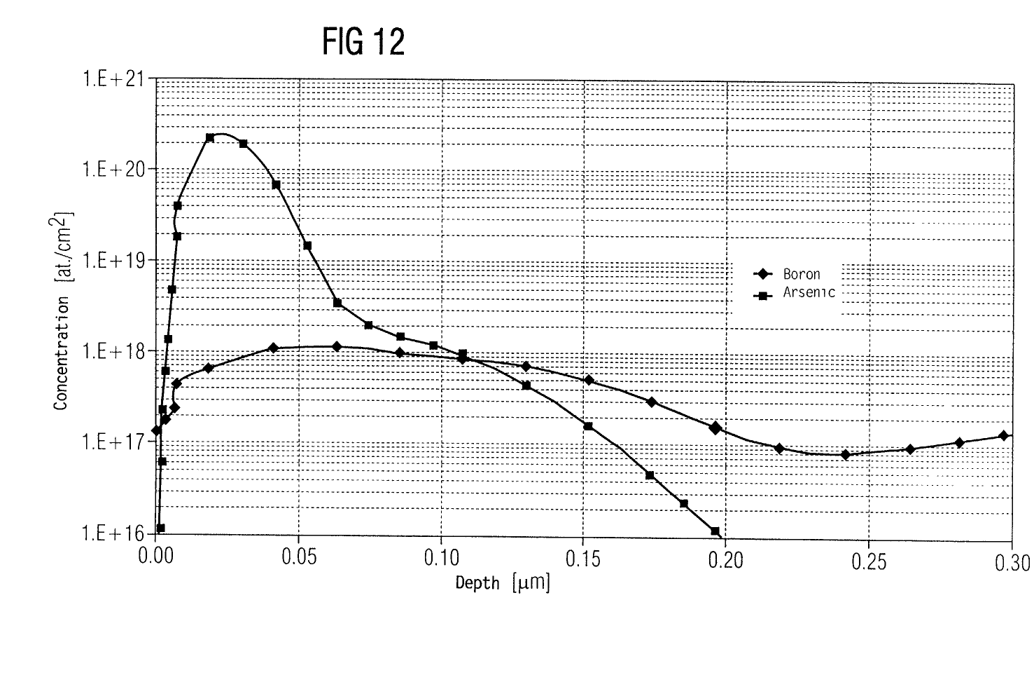

FIG. 12 shows the implantation profile according to a further embodiment of the invention in which the second implantation has been carried out with an energy level of 120 keV. The higher energy level causes the pn-type junction to lie at a depth of 115 nm, and the doping edge to drop away relatively gently toward the substrate. The resulting greater depletion depth leads to a reduction in the pn-type junction capacitance to only 0.980 fF/μm². This is 14% less than the same transistor without the second implantation step, while the overlapping capacitance Cₒᵥₗ changes only insignificantly at 0.209 fF/μm.

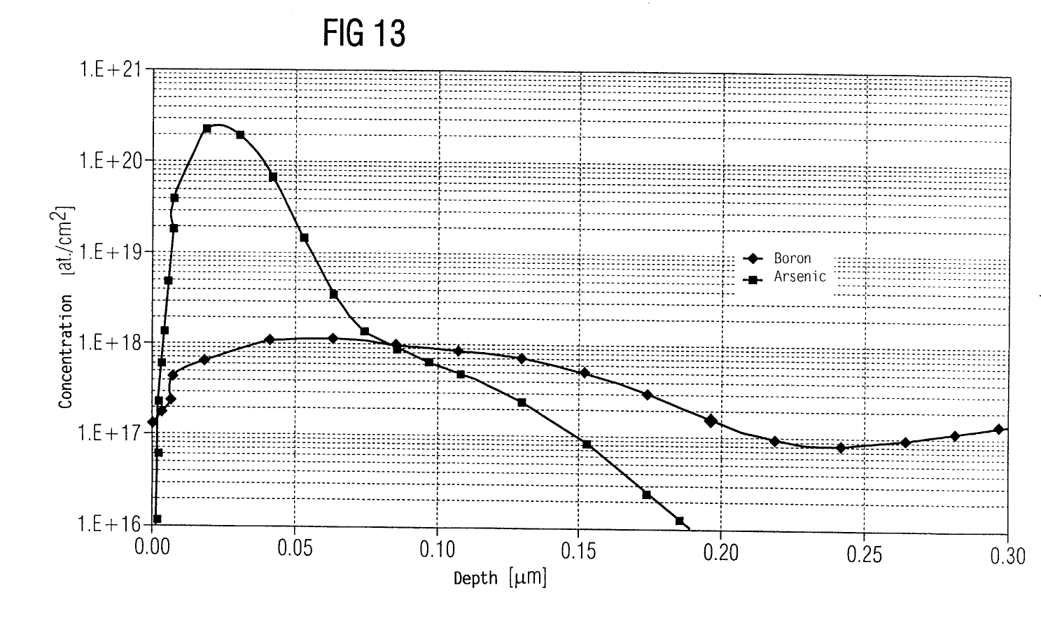

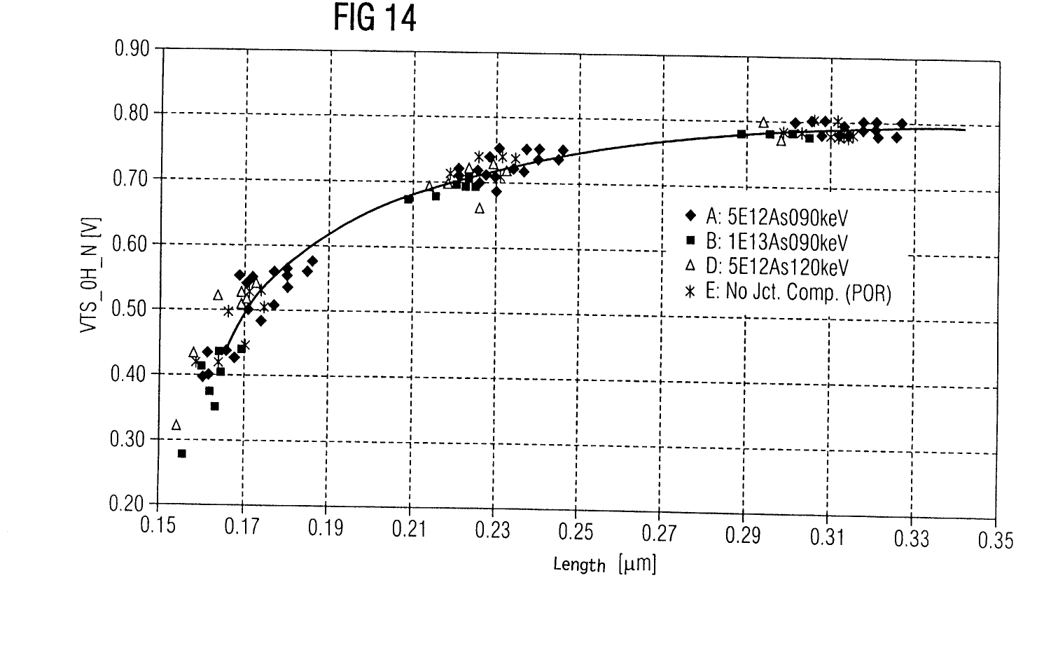

FIG. 13 shows the implantation profiles according to a further embodiment of the invention in which the second implantation step has been carried out with the dose of 5*10₁₂ cm⁻². The pn-type junction lies at a depth of 80 nm in this case. This leads to a reduction in the pn-type junction capacitance with respect to FIG. 9 to 1.042 fF/μm², while the overlapping capacitance Cₒᵥₗ changes only insignificantly at 0.206 fF/μm.

FIG. 14 shows an examination of the threshold voltages of n-type channel field effect transistors which have been manufactured in accordance with the prior art with implantation parameters as in FIG. 9, and in accordance with embodiments according to the invention with implantation parameters as in FIGS. 10 to 13. These investigations have been carried with different effective transistor channel lengths L_{eff}, between 150 nm and 350 nm. The investigation shows that the dropping away of the threshold voltage with very short effective channel lengths is very largely independent of whether the second implantation step has been carried out, and with which energy levels and doses it has been carried out. This is important evidence of the compatibility of the second implantation step with conventional methods so that the method according to the invention can be applied in an existing method for manufacturing field effect transistors without a large degree of expenditure.

Table 1 compares the changes in the capacitances of the pn-type junction of the described n-type channel MOSFETs according to the invention, the table also containing values of embodiments according to the invention with p-type channel field effect transistors (p-type channel MOSFETs).

Table 1: (energy level and dose for the second implantation)

TABLE 1
(energy level and dose for the second implantation)

| | | | Energy | | | |
|---|---|---|---|---|---|---|
| | | | level | Dose | Cⱼ | Cₒᵥₗ |
| | Substrate | Implant. | (key) | (cm⁻²) | (fF/μm²) | (fF/μm) |
| NMOS | Boron | As | 0 | 0 | 1.143 | 0.198 |
| NMOS | Boron | As | 90 | 5*10¹² | 1.105 | 0.200 |
| NMOS | Boron | As | 90 | 1*10¹³ | 1.081 | 0.201 |
| NMOS | Boron | As | 120 | 1*10¹³ | 0.980 | 0.209 |
| NMOS | Boron | As | 120 | 5*10¹² | 1.042 | 0.206 |
| PMOS | P | BF₂ | 0 | 0 | 1.427 | 0.263 |
| PMOS | P | BF₂ | 60 | 5*10¹² | 1.361 | 0.266 |
| PMOS | P | BF₂ | 60 | 1*10¹³ | 1.304 | 0.281 |
| PMOS | P | BF₂ | 80 | 1*10¹³ | 1.161 | 0.279 |
| PMOS | P | BF₂ | 80 | 5*10¹² | 1.289 | 0.276 |

We claim:

1. A method for manufacturing a field effect transistor, which comprises the steps of:
providing a substrate having a surface layer composed of a material of a first conductivity type;
producing a gate oxide layer on the substrate;
applying a gate electrode on the gate oxide layer;
carrying out a first implantation step for forming source/drain regions with a first dopant of a second conductivity type, with a first energy level and a first dose; and
carrying out a second implantation step with a second dopant of the second conductivity type, with a second energy level and a second dose, the second energy level being greater than the first energy level and the second dose being smaller than the first dose, with a result that a capacitance of a pn-type junction from the source/drain regions to the substrate is reduced.

2. The method according to claim 1, wherein the capacitance of the pn-type junction from the source/drain regions to the substrate is reduced by at least 3%.

3. The method according to claim 1, which comprises using a masking of the drain/source regions during the first implantation step and the second implantation step which is identical.

4. The method according to claim 1, which comprises setting the first dopant of the first implantation step to be equivalent to the second dopant of the second implantation step.

5. The method according to claim 1, wherein the capacitance of the pn-type junction from the source/drain regions to the substrate is reduced by at least 5%.

6. A method for manufacturing an integrated circuit, which comprises the step of:
producing a plurality of field effect transistors with the steps of:
providing a substrate having a surface layer composed of a material of a first conductivity type;
producing a gate oxide layer on the substrate;
applying a gate electrode on the gate oxide layer;
carrying out a first implantation step for forming source/drain regions with a first dopant of a second conductivity type, with a first energy level and a first dose; and
carrying out a second implantation step with a second dopant of the second conductivity type, with a second energy level and a second dose, the second energy level being greater than the first energy level and the second dose being smaller than the first dose, with a result that a capacitance of a pn-type junction from the source/drain regions to the substrate is reduced.

7. The method according to claim 6, which comprises forming the integrated circuit as an embedded dynamic random access memory.
